(19) United States
(12) Patent Application Publication
(10) Pub. No.: US 2024/0387270 A1
(43) Pub. Date: Nov. 21, 2024

(54) METHOD AND DEVICE FOR PRODUCING AND PREPARING ELECTRONIC COMPONENTS

(71) Applicant: EV Group E. Thallner GmbH, St. Florian am Inn (AT)

(72) Inventors: Jurgen Burggraf, St. Florian am Inn (AT); Markus Wimplinger, St. Florian am Inn (AT); Thomas Uhrmann, St. Florian am Inn (AT); Friedrich Paul Lindner, St. Florian am Inn (AT)

(73) Assignee: EV Group E. Thallner GmbH, St. Florian am Inn (AT)

(21) Appl. No.: 18/691,561

(22) PCT Filed: Oct. 19, 2021
(86) PCT No.: PCT/EP2021/078918

§ 371 Date: Mar. 13, 2024

(51) Int. Cl. H01L 21/78; H01L 21/02; H01L 21/67; H01L 21/683

(52) U.S. Cl. CPC H01L 21/78; H01L 21/02046; H01L 21/67028; H01L 21/6836; H01L 2221/68322; H01L 2221/68354

(57) ABSTRACT

The invention relates to a method and a device for the production and preparation of electronic components

### FIELD OF THE INVENTION

The present invention relates to a method and device for the production and preparation of electronic components.

### BACKGROUND OF THE INVENTION

A number of methods exist in the prior art for joining substrates together. In particular, there are also a number of methods in which individual components, which can also be perceived as substrates, are bonded to a larger substrate, for example a wafer. It is often necessary to ensure that an interface between the substrates or the components is free from contamination, in particular oxides or nitrides. In order to guarantee freedom from contamination, cleaning steps are carried out.

Furthermore, it is very often necessary to carry out a surface modification after the cleaning, which guarantees a better bond between the substrates and ensures the subsequent functionality of the components. These surface treatments are mainly of importance in direct bonding. In direct bonding, dielectric surfaces or semiconductor surfaces are, for the most part, bonded with one another. Of particular interest in this connexion is the bonding of so-called hybrid surfaces, which comprise a dielectric region, in particular an oxide, and electrical regions for the contacting.

The surface treatments often take place in the prior art after this the separation of the substrate into components, since the treated surfaces are damaged and contaminated during the separation. Carrying out a surface treatment on the individual components is not easily done, since the surfaces are small and therefore great demands are imposed on the accuracy and precision of the means for treating the surfaces. Furthermore, other surfaces or the vacuum environment may become contaminated by the surface treatments.

In the prior art, such process steps are preferably carried out in a vacuum environment. A drawback is that in a vacuum environment other process steps cannot be carried out at all or can only be so in a very poor manner.

One of the process steps which cannot be carried out without difficulty or not at all in a vacuum environment is the separation of a substrate (component substrate) into individual components. The separation of a substrate using mechanical, optical or chemical means usually leads to the generation of particles. Particles are undesirable in a vacuum environment, since they contaminate the entire vacuum environment. It is of course conceivable for the vacuum environment to comprise individual modules which are sealed off from one another, so that contamination is limited to one module. However, it is more advantageous to carry out the separation of a substrate into components outside a vacuum environment.

After a separation of substrates into individual components, the individual components undergo a surface treatment, so they can then be bonded better on a product substrate or a further component. In particular, the contamination-free provision of the individual components, in particular of the treated surfaces of the components, is of particular importance in this regard. In particular, the interface, which has specific properties in order to guarantee the functionality of the component, is located or arises between the component and the product substrate.

Devices and processes are described in the prior art, in which the component surfaces can be processed or cleaned by oxygen compounds and/or nitrogen compounds. The processing and cleaning of the component surfaces partially take place in each case in a device which can operate under a vacuum. However, the components are then removed again out of this device and thus exposed to the atmosphere. The freshly cleaned and activated component surfaces of the individual components are thus contaminated. The components are then bonded onto a product substrate in another device. Along this path, the component surfaces can again become contaminated. The number of defective components and the cost of processing is increased by the contamination.

It is an aim of the present invention, therefore, to specify a method and a device for producing and preparing components, which at least partially, in particular completely, remove the drawbacks listed in the prior art. In particular, it is the problem of the invention to specify an improved method and an improved device for producing and preparing components. In particular, it is an aim of the present invention to specify a method and a device for producing and preparing components, which reduce the rejection rate of the components. Furthermore, it is an aim of the present invention to specify a method and a device for producing and preparing components which can be carried out particularly reliably and free from contamination or which operates particularly reliably and free from contamination. Furthermore, it is an aim of the present invention to specify a method and a device for producing and preparing components, with which the treated surfaces, in particular the interfaces of the components provided for bonding, can be protected.

### SUMMARY OF THE INVENTION

The aforementioned aim is achieved through the features of the coordinated claims. Advantageous developments of the invention are indicated in the sub-claims. Any combinations of at least two of the features stated in the description, in the claims and/or the drawings also fall within the scope of the invention. Values lying within the stated limits are also deemed to be disclosed as limiting values in the stated value ranges and can be claimed in any combination.

Accordingly, the invention relates to a method for producing and preparing electronic components with at least the following steps in the following sequence:
i) preparation of a first substrate with a first substrate surface and a second substrate surface,
ii) carrying out a surface treatment on the first substrate surface, and then
iii) application of a protective layer on the treated first substrate surface,
iv) separation of the substrate into components.

Furthermore, the invention relates to a device for producing electronic componts, at least comprising surface treatment means for the surface treatment of a first substrate surface of a first substrate, means for applying a protective layer on the first substrate surface and separation means for separating the first substrate into components, wherein the device is constituted such that the first substrate surface can first be treated by the surface treatment means and then the protective layer can be applied on the treated first substrate surface.

The protective layer does not necessarily have to be a polymer protective layer. The protective layer can be a polymer, an oxide, a nitride, a metal, a metal alloy, etc. The protective layer can thus be electric or dielectric and therefore have a covalent, metallic or ionic bonding character. The protective layer is constituted such that it can subsequently be removed again, can preferably be completely removed. The removal of an oxide protective layer can be carried out for example with the aid of an ion cannon.

In the application for the invention, a protective layer on a polymer base is described by way of example. The use of a polymer as a protective layer is also particularly preferred.

By means of the method and the device, the surface treatments or the treated surfaces can advantageously be protected. The protective layer thus preserves the treated surfaces against contamination, in particular against contamination with particles which arise when the substrate is separated into components, and also against the atmosphere. The treated surface is thus advantageously preserved. Furthermore, the treated surfaces can advantageously be provided fully functional again at a later time, in particular shortly before the bonding. A flexible arrangement of the processes is thus advantageously possible. In addition, the first substrate can also be more easily transported after the application of the protective layer. During transport of the functionalised first substrate from the producer for further processing, in particular for separating into single units and for bonding on a product substrate, the treated surface can advantageously be protected.

The surfaces of the substrate or of the components that are to be protected are preferably hybrid bond surfaces. A hybrid bond surface is a surface predominantly including oxide, in which metallic components, in particular copper, are located. With regard to the method and the device, copper is particularly preferred. The metallic regions represent the contact points for the electrical contacting of the functional regions of the components. In such a case, a removal of oxygen compounds and nitrogen compounds by cleaning signifies stripping of the same, until the corresponding electrical regions have been exposed or cleaned. It is also conceivable that the surfaces to be protected are pure dielectric surfaces, in particular pure oxide surfaces.

Furthermore, the surface treatment can advantageously be carried out over the entire surface on the substrate to be separated into single units. Efficient production of the components is thus possible. In addition, the surfaces can be protected outside a vacuum against contamination by the atmosphere by means of the method and the device for the production and preparation of electronic components. An advantageous aspect of the invention is also the protection of the first component surfaces of a plurality of components, which are to be bonded to a substrate. In other words, by means of the application of a protective layer on the first substrate surface after its surface modification or surface treatment, the latter is retained during further process steps. The processes can thus be implemented much more flexibly. The defect rate of the electronic components is thus also reduced, since the contamination during the production and preparation is reduced overall.

In a preferred embodiment of the method for producing and preparing electronic components, provision is made such that the surface treatment in step ii) comprises at least cleaning, plasma treatment and/or coating of the first substrate surface. At least two of the aforementioned surface treatments preferably take place. All the necessary process steps which are to be carried out for a defect-free functionality and for bonding can thus advantageously be protected by the protective layer. Thus, no subsequent further surface treatment of the components has to be carried out before bonding. The components can thus be provided and used more flexibly. The production and preparation of the components can thus be carried out more efficiently with reduced contamination by the cleaning, plasma treatment and/or coating of the first substrate surface. In particular, separation of the substrate into single units can be advantageously carried out outside a vacuum environment. In this way, the treated surfaces protected by the protective layer can advantageously be provided shortly before the bonding. Contamination by the cleaning, plasma treatment or coating (surface treatments) themselves is thus also eliminated.

In a preferred embodiment of the method for producing and preparing electronic components, provision is made such that the cleaning includes at least chemical cleaning and/or physical cleaning, preferably by sputtering. In this way, the surfaces can be provided particularly clean and free from contamination. In particular, all oxide compounds and/or nitrogen compounds can be advantageously removed. In this regard, these cleaning measures are intended to guarantee a suitable surface.

In a preferred embodiment of the method for producing and preparing electronic components, provision is made such that the coating takes place with water for the hydrophilisation of the first substrate surface. This surface can thus advantageously be prepared for bonding with another component or a product substrate. Preferably, at least chemical cleaning first takes place, followed by at least physical cleaning, in particular removal of oxygen and/or nitrogen compounds, followed by at least a plasma treatment and/or coating, in particular with water. Semiconductor surfaces in particular are thus prepared for a subsequent direct bond.

In a preferred embodiment of the method for producing and preparing electronic components, provision is made such that, after the separation into single units in step iv), the components each comprise a first component surface and a second component surface, the protective layer being applied in each case on the first component surface. After the separation into single units, the functionality of the protected surface can thus advantageously be guaranteed. In addition, the individual components can thus be better transported, stored and used flexibly in further processes.

In a preferred embodiment of the method for producing and preparing electronic components, provision is made such that the components, after being separated into single units in step iv), are fixed with the second component surface on a carrier substrate. The fixing advantageously permits exact alignment and fixed positioning, in particular with respect to a product substrate. Furthermore, a plurality of components can advantageously be transferred simultaneously by the carrier substrate. An individual and regular arrangement of the components is thus ensured. An efficient transfer between different modules can thus be carried out. The treated surfaces of the components are protected by the protective layer on the first surface of the components.

In a preferred embodiment of the method for the production and preparation of electronic components, provision is made such that the first substrate, before the separation into single units in step iv), is provided with the second substrate surface on a second substrate. By positioning the substrate on the second substrate before the separation into single units, it can advantageously be ensured that the components, after the separation into single units, are pre-positioned in the desired manner on the second substrate. In addition, the components can then be transferred simultaneously with the second substrate.

In a preferred embodiment of the method for the production and preparation of electronic components, provision is made such that the first substrate, before the separation into single units in step iv), is provided with the first substrate surface comprising the protective layer on the second substrate. In other words, before the separation into single units, the first substrate lies with the protective layer on the second substrate. In this way, the treated surfaces can be better protected during the separation, since the separating means act on the first substrate in particular from the rear side, i.e. the second substrate surface of the first substrate. The treated surfaces are thus moved farther away from the influence of the separating means. In addition, an influence is closer to the second substrate or the surface of the second substrate facing the first substrate is as short as possible.

In a preferred embodiment of the method for the production and preparation of electronic components, provision is made such that the second substrate is a film. Films are particularly predestinated for the application, since a temporary fixing of the individual components is desired before the bonding. Furthermore, the components can easily be removed from the film and without great effort. In addition, the films are favourable and can be suitably selected for the individual case of application. Such films can advantageously be purchased already coated. For example, the films can be suitably precoated and selected in the optimum manner on the basis of the process parameters to be expected.

In a preferred embodiment of the method for the production and preparation of electronic components, provision is made such that the film comprises an adhesive layer and the first substrate is fixed on the adhesive layer. The adhesive layer provides reliable fixing of the first substrate or the individual components on the film. The adhesive layer is particularly well suited for easily detaching again the individual components from the film. In addition, a bonding layer is provided by the adhesive layer, which provides the least possible contamination of the components compared to alternative fixing options.

In a preferred embodiment of the method for the production and preparation of electronic components, provision is made such that the method further includes the following step after the separation into single units in step iv): v) the removal of the protective layer from the first component surface of the components. The pre-treated surface can advantageously be prepared for the bonding by the removal of the protective layer. A further surface treatment, in particular cleaning, is thus not necessary after the separation into single units. In addition, the protective layers of the individual components can be suitably removed individually and in an appropriately timed manner for the processing status of the surface to be bonded.

In a preferred embodiment of the method for the production and preparation of electrical components, provision is made such that the removal of the protective layer in step v) is carried out under vacuum. The pressure in the vacuum amounts to less than 1 bar, preferably less than 1 mbar, still more preferably less than 10⁻⁵ mbar, most preferably less 10⁻⁹ mbar, with utmost preference up to 10⁻¹² mbar. In this way, renewed contamination of the treated surfaces by the atmosphere can advantageously be prevented. Furthermore, a large part of the process can advantageously be carried out under vacuum, since some surface treatments can only be carried out poorly under vacuum. The treated surface of the components can thus be provided particularly reliably and contamination-free.

In a preferred embodiment of the method for the production and preparation of electronic components, provision is made such that, before the removal of the protective layer in step v), the components are taken over by a pick-and-place tool with the second component surface and fixed on the pick-and-place tool. The components lie with the treated surface comprising the protective layer on the second substrate and are thus particularly well protected. By means of the pick-and-place tool, individual taking-over and transfer of the components is possible. In addition, the components can be aligned particularly exactly with the surface to be bonded. In this way, specific components can be taken over and fixed selectively. For example, only components can be taken over which have previously passed an electrical test or have a specific property, which is required of the product substrate to be bonded. The components are advantageously contacted at the second component surface. Contacting of the treated first component surface is thus not necessary. The easily accessible second component surface can be particularly easily contacted by the pick-and-place tool and taken over. In this way, a component rotation for the bonding of the first component surfaces, in particular for the bonding with a product substrate, is advantageously not required.

In a preferred embodiment of the method for the production and preparation of electronic components, provision is made such that the removal of the protective layer takes place while the components are fixed on the pick-and-place tool. Removal of the protective layer can thus be carried out individually and without risk to adjacent components. Furthermore, the removal of the protective layer can advantageously be carried out at another place. A risk to the second substrate due to the means for removal of the protective layer or other components is also not possible.

An advantageous aspect of the method for the production and preparation is the protection of the surfaces of a plurality of components, which are to be bonded to a substrate. A particularly advantageous aspect includes that the surface modification of a substrate is protected by a coating of this substrate with a protective layer. The surface modification is for example, and advantageously, a plasma treatment. As a result of the application of a protective layer on the substrate surface after its surface modification, the surface modification is retained over further process steps. The processes can thus be carried out much more flexibly. In addition, the defect rate of the electronic components is also reduced, since the contamination during the production and preparation is reduced.

It is therefore a further aspect of the method and the device for the production and preparation, that necessary process steps for the treatment of a surface can be carried out before the coating of the surface with a protective layer. The advantage includes in particular that the process steps that are required for the production of an article can be carried out at the start of the process.

### Component

A component, in particular an electronic component, is understood in the context of the description to be an, in particular, functional object which is bonded onto a substrate. A component is preferably a chip, a MEMS, an LED, a microchip or similar components. The latter are produced in particular from a substrate. The component either itself comprises component alignment marks or use is made of geometric characteristics such as corners, lines or structures on the component as component alignment marks.

### First Substrate/Component Substrate

A first substrate or a component substrate is understood to be a substrate which is used for the production of components. The functional regions of the subsequent components are preferably produced in a wafer-level process. In this process, numerous process steps may be required in order to generate the functionality of the subsequent components. At the end of this process, a separation of the substrate into single units is carried out. It is for example conceivable for a separation of the components from the substrate to be carried out with the aid of a saw, a wire, a laser or other means.

### Second Substrate/Carrier Substrate

A second substrate or a carrier substrate is understood to be a substrate, with which the components are relatively aligned and temporally bonded. It serves solely for the temporary take-over of the components.

The second substrate comprises in particular a plurality of alignment marks along the carrier substrate surface, which are used for the alignment of the components relative to the second substrate. These alignment marks can thus also be referred to as component alignment marks. Furthermore, the second substrate can have alignment marks, in order to be able to align the second substrate relative to a third substrate. These alignment marks can thus also be referred to as substrate alignment marks. The second substrate can include any material, in particular of a film stretched on a frame.

### Third Substrate/Product Substrate

The third substrate or product substrate is the substrate onto which the components are transferred from the second substrate. The third substrate preferably comprises alignment marks so that it can be aligned relative to the second substrate. These alignment marks, as in the case of the second substrate, are referred to as substrate alignment marks. The product substrate or the product substrate stack has surfaces, onto which the components are to be bonded with the first component surface, i.e. with the surface having the surface treatment. By means of the surface treatment, the first substrate surface or the first component surface in particular is matched in the optimum manner to the surface of the product substrate, so that the bond properties between the surfaces to be bonded are optimum.

### Module System

A module system, sometimes also referred to as a vacuum device or cluster, is understood to mean a number of associated modules. Each module comprises at least one unit. The characteristic feature of the module system is that substrates are not exposed to the atmosphere between different process steps and work can thus always be carried out under a vacuum. A particularly preferred feature of the proposed module system is that substrates or the components fixed on the second substrate are not exposed to the atmosphere between different process steps and work can thus be carried out constantly under a vacuum. Once a substrate is in the module system, it goes on to be treated in particular in an optimum vacuum environment. Furthermore, all the modules of the module system can be evacuated individually.

Several special modules are described in the following text, which are preferably part of the module system, in order to be able to implement the method for the production and preparation. The modules are therefore also listed in the sequence of use in the production process.

The transport of substrates or substrate stacks in the module system preferably takes place by means of a robot, which is located in the centre of the module system or can move along a rail system.

The module system can thus be regarded as a device for the production and preparation.

### Coating Module

The module system or the device for the production and preparation comprises a coating module. A bonding layer and/or the protective layer can thus be applied on the substrate. In this regard, the coating module forms the means for the application of a protective layer. The bonding layer is particularly preferably applied on the second substrate surface or on the second component surface for simpler bonding. The coating module, however, is optional. It is conceivable, for example, for a substrate to be coated with the bonding layer and/or the protective layer outside the module system and only thereafter to be introduced into the module system. This is advantageous especially when the producer of the functionalised first substrate provides the first substrate with a protective layer immediately after the functionalisation or surface treatment.

If a coating module in present in the module system, at least one bonding layer should thus be able to be applied therewith. This would, in contrast with the protective layer, be unnecessarily contaminated during the transport from the producer of the functionalised substrate to the module system.

### Module for Separating into Single Units

If the module system has a module for separation into single units, the substrate can be separated into single units in the module system. It would also be conceivable for the separation into single units also to take place outside the module system and for the components already separated into single units to be delivered into the module system.

### Pick-and-Place Module

The pick-and-place module has the task of taking over the individual components and aligning them on the carrier substrate or the second substrate. Furthermore, the alignment and the contacting of the components relative to the product substrate is carried out by means of the pick-and-place module. The pick-and-place module can simply take over, align, position and bond the components, in particular during the coating of the first surface-treated substrate surface with a protective layer before the separation into single units. If the carrier substrate itself has been coated over the whole area with a bonding layer or the second substrate comprises an adhesive layer, the components are directly bonded on the bonding layer on the carrier substrate or fixed on the adhesive layer.

### Cleaning Module

The cleaning module forms in particular the means for removing the protective layer from the components. It is conceivable for the cleaning module also to be located outside the module system. In this case, the components would be delivered into the module system without the protective layer. In a particularly preferred embodiment, however, the cleaning module is also part of the module system, in order that the protective layer is first advantageously removed inside the vacuum and the treated surfaces do not therefore come into contact with an atmosphere.

### Surface Treatment Module

The surface treatment module is a part of the device for the production and preparation of electronic components. The first substrate surface is treated with the surface treatment module. The first substrate surface is in particular cleaned and the bonding properties are improved, for example by means of surface activation measures, plasma treatments or the application of a further layer. In particular, the treatment of the component surfaces is understood to mean a removal of oxygen compounds and/or nitrogen compounds. Since the first component surfaces are still more reactive after the removal of oxygen compounds and/or nitrogen compounds and may no longer be exposed to the atmosphere, the surface treatment module is preferably a part of the module system. The surface treatment module can for example be a plasma chamber or an ion beam chamber. It is preferably an ion beam chamber, as in publication WO2015197112A1.

In particular, the surface treatment module comprises means for the activation of the first component surfaces or the first substrate surface.

It is also conceivable for a hydrophilisation of the first component surfaces or the first substrate surface to take place in the surface treatment module.

It is also conceivable for specific layers to be applied in the surface treatment module, which further improve the bond between the components and the product substrate.

### Bonding Module

After the first component surfaces or the first substrate surface have been treated in the surface treatment module, the bonding of the components with the first component surface on a product substrate in particular takes place. The protective layer on the treated component surfaces is removed before the bonding. For this purpose, the product substrate is aligned relative to the carrier substrate or the pick-and-place tool aligns the components taken over relative to the product substrate. The bonding module then bonds the aligned or positioned components on the product substrate. The alignment preferably takes place by means of alignment marks, which are located on the carrier and product substrate. The bonding module thus preferably comprises an optical alignment system. Furthermore, the bonding module preferably comprises means for contacting the product substrate with the components.

### Debonding Module

After the contacting of the product substrate with the components, the connection between the components and the carrier substrate may be weakened or completely removed. If the components have been bonded on the carrier substrate, debonding means can reduce the bonding properties between the second component surfaces and the carrier substrate. If the components are transferred and in particular separated into single units on a second substrate, in particular a film, the pick-and-place tool can function as a debonding means. With such means for debonding, the transfer can advantageously be carried out selectively if only specific components are debonded.

The following exemplary methods show in particular the most important process steps that are required for the method for the production and preparation. The expert in the field knows that a plurality of further, not explicitly mentioned, process steps can certainly be part of the method.

### Surface Treatment

A surface treatment is understood in particular to be any influencing of the surface, with the aid of which an improved bonding property of the substrate surface with another surface, in particular another substrate surface, can be produced. A surface treatment thus includes in particular
Cleaning measures, in particular
   chemical cleaning measures
   physical cleaning measures, in particular
      by sputtering, in particular
         removal of oxide compounds
         removal of nitrogen compounds
Plasma treatments, in particular
   for the generation of a reservoir
   for setting a surface roughness
Coatings, in particular
   with water for the hydrophilisation of the substrate surface.

The surface roughness is indicated either as a mean roughness, root-mean-squared roughness or averaged roughness depth. The determined values for the mean roughness, the root-mean-squared roughness and the averaged roughness depth generally differ for the same measurement distance or measurement area, but lie in the same range of order of magnitude. The following numerical value ranges for the roughness are therefore to be understood either as values for the mean roughness, the root-mean-squared roughness or for the averaged roughness depth. The roughness is less than 100 μm, preferably less than 10 μm, still more preferably less than 1 μm, most preferably less than 100 nm, with utmost preference less than 10 nm.

A measure for the hydrophobicity or hydrophilicity is the contact angle that is formed between a test liquid droplet, in particular water, and the surface to be measured. Hydrophilic surfaces flatten the liquid droplet, since the adhesive forces between the liquid and the surface dominate over the cohesive forces of the liquid and therefore form small contact angles. Hydrophobic surfaces lead to a more spherical shape of the liquid droplet, since the cohesive forces of the liquid dominate over the adhesive forces between the liquid and the surface. With regard to the method and the device, hydrophilic substrate surfaces are preferred, in particular since the latter are particularly well suited for fusion bonding. The contact angle, therefore, is in particular less than 90°, preferably less than 45°, still more preferably less than 20°, most preferably less than 5°, with utmost preference less than 1°.

The cleanness of the substrate surface is preferably described by the number and size of the, in particular organic, residues. The residues arising on a substrate surface are in particular smaller than 100 nm, preferably smaller than 90 nm, still more preferably less than 80 nm, most preferably less than 70 nm, with utmost preference less than 60 nm. The number of residues present with a selected maximum size is in particular less than 1000 particles/wafer, preferably less than 500 particles/wafer, still more preferably less than 250 particles/wafer, most preferably less than 100 particles/wafer, with utmost preference less than 50 particles/wafer.

The surface treated by the surface treatment forms the interface with the product substrate after the bonding process.

Generally, the arising interface can be referred to as optically and/or mechanically and/or thermally and/or electrically ideal. Ideal means that the best possible optical and/or mechanical and/or thermal and/or electrical properties that can be achieved are achieved by the surface treatment, in particular by the removal of harmful oxides and/or nitrides.

Mechanically ideal means that the mechanical properties, in particular the bonding strength, of the interface enable the most efficient possible bonding between the component and the product substrate. Especially for a hydrophilic fusion bond, which preferably is brought about by contacting of an oxide surface on the component and/or an oxide surface on the product substrate, the bonding strength between the component and the product substrate is characterised with the aid of the surface energy that is required to separate a unit area of one square metre. The bonding strength is in particular greater than 0.5 J/m2, preferably greater than 1.0 J/m2, still more preferably greater than 1.5 J/m2, most preferably greater than 2.5 J/m2, with utmost preference greater than 2.5 J/m2.

Optically ideal means that electromagnetic radiation can pass through the interface in the best possible way, i.e. preferably without or with very little loss of intensity. The transmittivity is in particular greater than 10%, preferably greater than 50%, preferably greater than 75%, most preferably greater than 95%, with utmost preference greater than 99%.

Thermally ideal means that a heat flow can pass through the interface in the best possible way, i.e. preferably without or with very little loss of heat. The heat loss is in particular less than 50%, preferably less than 25%, preferably less than 10%, most preferably less than 5%, with utmost preference less than 1%.

Electrically ideal means that the electrical conductivity via the interface is as high as possible. The electrical conductivity should be greater than 1 S/m. preferably greater than 10 S/m, preferably greater than 102 S/m, most preferably greater than 10⁴ S/m, with utmost preference greater than 10⁶ S/m. If surfaces of the components and/or the regions of the product substrate on which the components are bonded are hybrid surfaces, the data for the electrical conductivity then applies only for the electrical regions.

The listed surface treatments can be combined with one another. Preferably, at least chemical cleaning is first carried out, followed by at least physical cleaning, in particular a removal of oxygen compounds and nitrogen compounds, followed by at least a plasma treatment and/or coating, in particular with water. Within the scope of a surface treatment, the first substrate surface is particularly preferably first cleaned and then activated, so that the bonding properties with regard to the surface of the product substrate to be bonded are optimum. In particular, semiconductor surfaces are thus prepared for subsequent direct bonding.

The surface treatment of an oxygen surface is also conceivable, wherein the oxide is to be retained. In this case, the (complete) removal of the oxide is dispensed with and the oxide is treated such that the bonding properties are optimum.

The following proposed methods for the production and preparation of components comprise in particular the most important process steps. The expert in the field knows that a plurality of further, not explicitly mentioned, process steps can of course be part of the method.

### First Method

In a first process step of a first exemplary method, a first substrate surface of a prepared first substrate is treated. The surface treatment comprises at least one of the listed surface treatments.

In a second process step of a first exemplary method, the first surface-treated substrate surface is provided with a protective layer. The protective layer prevents the subsequent process steps from at least partially reversing or impairing the surface treatment. In particular, the deposition of the protective layer should not itself have any influence on the surface treatment, in particular on a surface modification. In an extension of the first method, a bonding layer can be applied on the second substrate surface lying opposite the first substrate surface. This bonding layer is preferably an adhesive layer, preferably a polymer. Such bonding layers are regularly used in temporary bonding and are known to the person skilled in the art.

In a third process step of the first exemplary method, a separation of the first substrate into single units takes place. The separation into single units leads to individual components, in particular to chips. The protective layer deposited on the first substrate surface prevents the surface treatment of the first substrate surface of the first substrate from being influenced or impaired during the separation in two single units.

In a fourth process step of a first exemplary method, the individual components are bonded with their second substrate surface onto the first substrate surface of a second substrate. The second substrate is in particular a carrier substrate, which is intended to take over the components temporally, in order to bond them in a subsequent process step simultaneously with their surface-treated, first component surface to a first substrate surface of a third substrate. The positioning of the components on the second substrate preferably takes place with the aid of a pick-and-place tool. The components are aligned particularly preferably with respect to optical alignment marks, which are distributed over the second substrate. The alignment marks are referred to as component alignment marks. The second substrate preferably comprises further alignment marks, which in a subsequent process step permit the alignment of the second substrate with respect to the third substrate. The alignment marks are referred to as substrate alignment marks.

In a fifth process step of a first exemplary method, the protective layer is removed from the first substrate surface of the first substrate. The surface treatment should not be influenced or only negligibly so by the removal of the protective layer. Very particularly preferably, the removal of the protective layer takes place in a vacuum environment.

In a sixth process step of a first exemplary method, this second substrate is aligned relative to a third substrate and contacted with the component surfaces of the components.

In a seventh process step of a first exemplary method, the components are separated from the second substrate, in particular by means of debonding means.

### Second Method

In a first process step of a second exemplary method, a first substrate surface of a first substrate is treated. The surface treatment comprises at least one of the listed surface treatments.

In a second process step of a second exemplary method, the first substrate is fixed with its second substrate surface on a second substrate. The second substrate is in particular a film. The film is preferably stretched on a frame. The film is preferably already provided with an adhesive layer. The adhesive layer thus forms in particular a bonding layer, similar to the first method.

The first and second process step can in particularly be exchanged, so that the first substrate is first fixed with the second substrate surface on the film and only then does the surface treatment of the first substrate surface take place.

In a third process step of a second exemplary method, the first, surface-treated substrate surface is provided with a protective layer. The protective layer prevents subsequent process steps from unfavourably influencing or impairing the surface treatment. In particular, the deposition of the protective layer should not itself have any influence on the surface modification.

In a forth process step of a second exemplary method, separation of the first substrate into single units takes place. The separation into single units leads to individual components, in particular chips. The effect of the protective layer deposited on the first substrate surface is that the surface treatment of the first substrate surface of the first substrate is not at least partially reversed or impaired during their separation into single units. In particular, the separation into single units is not carried out until the first substrate has been fixed with its second substrate surface lying opposite the first substrate surface on a film. The film preferably already has an adhesive layer, so that the application of a bonding layer as in the second process step of the first exemplary method can be dispensed with. Such films can be purchased already coated. The film corresponds to the second substrate of the first exemplary method and is referred to in particular as the second substrate. In this second method, it is not necessary to align the individual components with respect to this second substrate in the optimum manner. If the separation of the first substrate into single units takes place only after the contacting with the film, an exact alignment is barely possible. The film serves in particular as a second substrate and for the transfer of the components.

In a fifth process step of a second exemplary method, the protective layer is removed from the individual components. The surface treatment should not be influenced or only negligibly so by the removal of the protective layer. Very particularly preferably, the removal of the protective layer takes place in a vacuum environment.

In a sixth process step of a second exemplary method, the individual components can be taken over from the second substrate and fixed using a suitable pick-and-place tool. The components are then bonded on a third substrate or another component or another component stack. When the components are taken over by the pick-and-place tool, the first component surfaces are contacted. In this regard, the components are rotated before bonding, since the components should be bonded on the product substrate with the first and surface-treated component surface. The process for removing the components from the film, in particular a possible process for the rotation of the components, such as a chip flip, is not described in detail here, since they are known to the expert in the field.

### Third Method

In a first process step of third exemplary method, a first substrate surface of a first substrate is treated. The surface treatment includes at least one of the listed surface treatments.

In a second process step of a third exemplary method, the first, surface-treated, substrate surface is provided with a protective layer. The protective layer prevents subsequent process steps from at least partially reversing or impairing the surface treatment. In particular, the deposition of the protective layer should not have any influence on the surface modification.

In a third process step of a third exemplary method, the first substrate is fixed with its first substrate surface on a second substrate. The second substrate is in particular a film. The film is preferably stretched on a frame. The film is preferably already provided with an adhesive layer. In contrast with the second method, therefore, the first substrate is fixed with the substrate surface, which has been surface-treated, on the second substrate. In this case, the adhesive layer of the film of the second substrate can assume the function of a protective layer.

In a fourth process step of a third exemplary method, the separation of the first substrate into single units takes place. The separation into single units leads to individual components, in particular to chips. The effect of the protective layer and/or the adhesive layer deposited on the first substrate surface is that the surface treatment of the first substrate surface of the first substrate is prevented from being at least partially reversed or impaired during the separation into single units. In addition, the orientation of the components advantageously prevents the first component surface facing the second substrate from becoming damaged. In other words, the treated surface is protected by the component itself or by the first substrate itself. The separation into single units is in particular first carried out after the first substrate has been fixed on a film with its first substrate surface lying opposite the second substrate surface. In this regard, the protective layer lies on the second substrate. The film preferably already comprises an adhesive layer, so that the application of a bonding layer as in the second process step of the first method can be dispensed with. Such films can be purchased already coated. The film corresponds to the second substrate of the first method and therefore is also referred to in this second method as a second substrate. It is not necessary and also not desired in the third method to align the individual components in the optimum manner with respect to the second substrate. If the separation of the first substrate into single units takes place only after the contacting on the film, this also is barely possible.

In a fifth process step of a third exemplary method, the individual components can be removed from the second substrate using a suitable pick-and-place tool. The advantage of the third method includes in particular that the pick-and-place tool is capable of contacting the components at their second component surfaces, i.e. at the previous second substrate surface, at which no surface treatment has been carried out. The first component surfaces, i.e. the previous first substrate surface, at which a surface treatment has been carried out remain freely accessible. A component rotation, such as a chip flip, is not necessary in this preferred method.

In a sixth process step of a third exemplary method, the protective layer is removed from the individual components. If the second process step has been omitted, however, cleaning can then be carried out, since the surface treatment was in contact with the adhesive layer of the film of the second substrate. The surface treatment should not be affected or only negligibly so by the removal of the protective layer and/or the adhesive layer. The removal of the protective layer and/or the adhesive layer preferably takes place in a vacuum environment. After being taken over by a pick-and-place tool, the first component surface with the surface treatment is immediately available and can be used directly for a bonding process. In particular, removal of the protective layer can thus advantageously be carried out, while the component is fixed on the pick-and-place tool. In this way, no adjacent components or the second substrate are at risk during the removal. In addition, the particles of the protective layer can be removed in a targeted manner in a vacuum environment, in particular in another module. Contamination of the second substrate or the adjacent components by the particles of the protective layer is thus reduced.

### BRIEF DESCRIPTION OF THE DRAWINGS

Further advantages, features and details of the invention emerge from the following description of preferred examples of embodiment and with the aid of the drawings. Diagrammatically:

FIG. 1a shows a first process step of a first exemplary method,

FIG. 1b shows a second process step of a first exemplary method,

FIG. 1c shows a third process step of a first exemplary method,

FIG. 1d shows a fourth process step of a first exemplary method,

FIG. 1e shows a fifth process step of a first exemplary method,

FIG. 1f shows a sixth process step of a first exemplary method,

FIG. 1g shows a seventh process step of a first exemplary method,

FIG. 2a shows a first process step of a second exemplary method,

FIG. 2b shows a second process step of a second exemplary method,

FIG. 2c shows a third process step of a second exemplary method,

FIG. 2d shows a fourth process step of a second exemplary method,

FIG. 2e shows a fifth process step of a second exemplary method,

FIG. 3a shows a first process step of a third exemplary method,

FIG. 3b shows a second process step of a third exemplary method,

FIG. 3c shows a third process step of a third exemplary method,

FIG. 3d shows a fourth process step of a third exemplary method,

FIG. 3e shows a fifth process step of a third exemplary method,

FIG. 3f shows a sixth process step of a third exemplary method,

FIG. 4 shows a plan view of a second substrate with the most important components and features and

FIG. 5 shows a plan view of a module system.

### DETAILED DESCRIPTION OF THE INVENTION

Identical components or components with the same function are denoted by the same reference numbers in the figures. The figures are diagrammatic representations. In particular, the ratios of the individual components are not correct. A thin layer 13 is selected as a graphic representation of a treated substrate surface, i.e. a surface treatment 13. Surface treatment 13 is generally representative of a number of different treatments of substrate surface 1o. For example, the surface treatment can include cleaning and thus shows a cleaned surface. In addition, surface treatment 13 can be a further thin layer, for example a water layer. In order to cover all possibilities, however, the representation of surface treatment 13 as a thin layer is used in the figures.

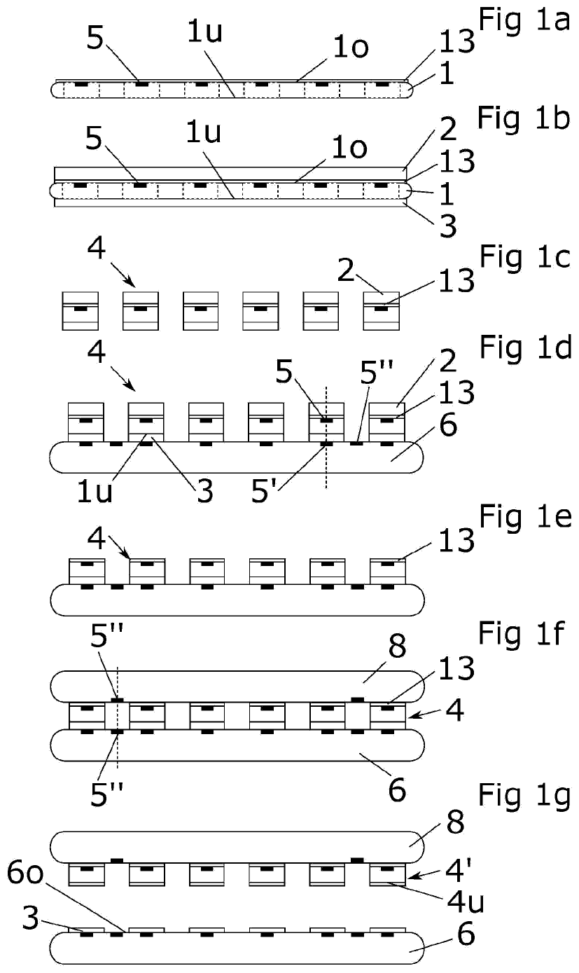

FIG. 1a shows a first process step of a first exemplary method, in which first substrate surface 1o of a first substrate 1 is treated. Surface treatment 13 is a layer and not just a state of first substrate surface 1o, such as for example a cleaned or a plasma-treated first substrate surface 1o or a first substrate surface provided with a reservoir. Generally, component alignment marks 5 are located on first substrate 1, with the aid of which subsequently separated components 4 (see FIG. 1c) are aligned relative to carrier substrate 6.

FIG. 1b shows a second process step of a first exemplary method, in which the protection of surface treatment 13 is represented by a protective layer 2. First substrate 1 can be provided on its second substrate surface 1u lying opposite first substrate surface 1o with a bonding layer 3, which enables subsequent fixing of individual components 4 (see FIG. 1c) on a carrier substrate 6.

FIG. 1c shows a third process step of a first exemplary method, in which a separation a first substrate 1 (see FIG. 1b) into individual components 4 takes place. In particular, surface treatment 13 is protected by protective layer 2.

FIG. 1d shows a fourth process step of a first exemplary method, in which individual components 4 are aligned with and bonded to a second substrate 6 with their second substrate surface 1u, on which a bonding layer 3 is preferably located. Alignment marks 5 of components 4, which are also referred to as component alignment marks, are preferably used to enable alignment of components 4 relative to alignment marks 5′ of second substrate 6. Second substrate 6, moreover, preferably comprises alignment marks 5″, which are also referred to as substrate alignment marks, with the aid of which an alignment of third substrate 8 relative to second substrate 6 can be carried out in the subsequent sixth process step. As from this process step it is possible to transport the equipped second substrate 6 into a module system 9 (see FIG. 5). Surface treatment 13 has already been carried out and also continues to be on the first component surface, whilst the separation of first substrate 1 into individual components 4 has preferably been carried out outside a module system 9.

FIG. 1e shows a fifth process step of a first exemplary method, in which protective layer 2 (no longer shown) is removed. The removal of protective layer 2 preferably takes place in a module system 9 (see FIG. 5), in which all modules 10, 10′, 10″, 10′″, 10″″ are connected to one another in such a way that a vacuum can be continuously generated and maintained in entire module system 9. Surface treatment 13 thus advantageously no longer comes into contact with the atmosphere.

FIG. 1f shows a sixth process step of a first exemplary method, in which a third substrate 8 is aligned relative to second substrate 6 with the aid of alignment marks 5″ that are present.

A particularly efficient bond between components 4 and third substrate 8 is enabled by means of surface treatment 13. In FIG. 1f, it is shown how components 4 of second substrate 6 are directly connected to third substrate 8.

FIG. 1g shows a seventh process step of a first exemplary method, in which a separation of first substrate 6 from third substrate 8 takes place. Components 4 become detached with their second component surface 4u from second substrate 6. This separation is referred to as debonding. The debonding can take mechanically and/or thermally and/or chemically and/or with the aid of electromagnetic beams, in particular lasers. Cleaning of component surfaces 4u and/or first substrate surface 6o of second substrate 6 then preferably takes place. Second substrate 6 can then preferably be reused.

In a particular extension of this first exemplary method for production and preparation, further components can already be present on third substrate/product substrate 8 as from the sixth process step in FIG. 1f. Contacting of components 4 by second substrate 6 and further components by third substrate 8 thus takes place. A plurality of component-to-component stacks, in particular chip-to-chip stacks, can thus be produced or provided particularly efficiently. These component-to-component stacks are simply referred to subsequently as component stacks.

The use of a second substrate 6A (not represented) would be conceivable, which is equipped with components 4, these being logic switching circuits, for example microprocessors. Furthermore, a second substrate 6B could be produced, which is equipped with components 4 which are memory components, for example a random access memory component. The second substrate with reference A for example is then first bonded to third substrate 8, which is the subsequent product substrate. The second substrate with reference B is then aligned relative to third substrate 8 and components 4 of the second substrate with reference B are bonded to first components 4, which are already located on third substrate 8. A third substrate 8 is thus obtained with a number of component stacks, wherein each component stack includes components with a generally different functionality. The expert in the field also understands that this process can be repeated with a plurality of components in order to produce component stacks with any number of components. It is preferable that the respective new component layer with components 4 from a second substrate 6 always comprises a surface treatment 13 and can thus be bonded particularly efficiently to the last transferred layer of components 4 which is located on third substrate 8.

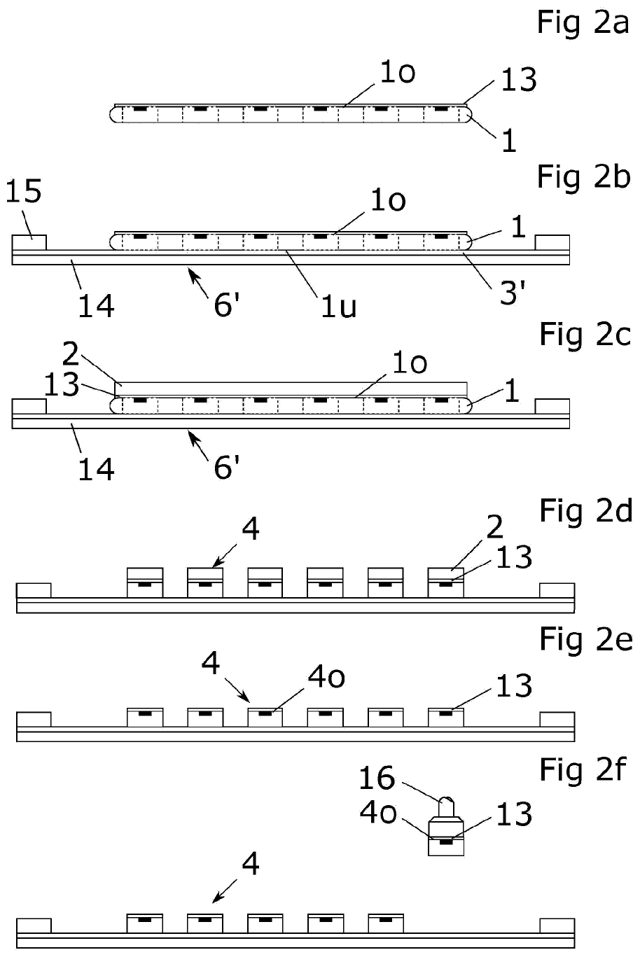

FIG. 2a shows a first process step of a second exemplary method. A first substrate 1 is provided at its first substrate surface 1o with a surface treatment 13.

FIG. 2b shows a second process step of a second exemplary method, in which first substrate 1 is fixed with its second substrate surface 1u lying opposite first substrate surface 1o on a second substrate 6′. Second substrate 6′ is in particular a film 14, on which an already deposited adhesive layer 3′, which can also be referred to as a bonding layer, is located. Most film producers will already provide a film 14 with an adhesive layer 3 during production. Film 14 can then be obtained in the trade with adhesive layer 3′. Film 14 is preferably stretched on a frame 15.

It is also conceivable for the two previous process steps to be exchanged, i.e. for substrate 1 first to be fixed on film 14 of second substrate 6′and for surface treatment 13 only then to be obtained. This is advantageous, since first substrate 1 then no longer has to be contacted, but rather the handling and the transport take place via second substrate 6′. A drawback, however, is that film 14 can also be affected, in particular unfavourably, due to several surface treatments 13. The sequence is therefore preferably fixed for the given individual case.

FIG. 2c shows a third process step of a second exemplary method, in which the protection of surface treatment 13 is represented by the application of a protective layer 2 on treated surface 1o. A protective layer 2 is deposited on surface-treated first substrate surface 1o or surface treatment 13. In this case, it is also conceivable for the coating with protective layer 2 to already be carried out before substrate 1 is fixed on second substrate 6′.

FIG. 2d shows a fourth process step of a second exemplary method, in which first substrate 1 is separated into individual components 4. Surface treatment 13 is thereby protected by protective layer 2. This separation into single units preferably takes place outside a module system 9. At the latest after the separation into single units, second substrate 6′ can however be transported into a module system 9 (see FIG. 5).

FIG. 2e shows a fifth process step of a second exemplary method, in which protective layer 2 (no longer shown) is removed from first component surfaces 4o of components 4.

The removal of protective layer 2 preferably takes place in a module system 9, in which all modules 10, 10′, 10″, 10′″, 10″″ are connected to one another in such a way that a vacuum can be generated and maintained continuously in entire module system 9. Surface treatment 13 thus preferably no longer comes into contact with the atmosphere.

FIG. 2f shows a sixth process step of a second exemplary method, in which components 4 are individually removed and further processed. Pick-and-place tool 16 contacts the components at treated component surface 4o.

In an alternative embodiment of the exemplary second method, instead of the individual removal of components 4 according to FIG. 2f, analogous to the sixth process step of the first exemplary method according to FIG. 1f, a third substrate 8 is aligned relative to second substrate 6′ and brought into contact with components 4.

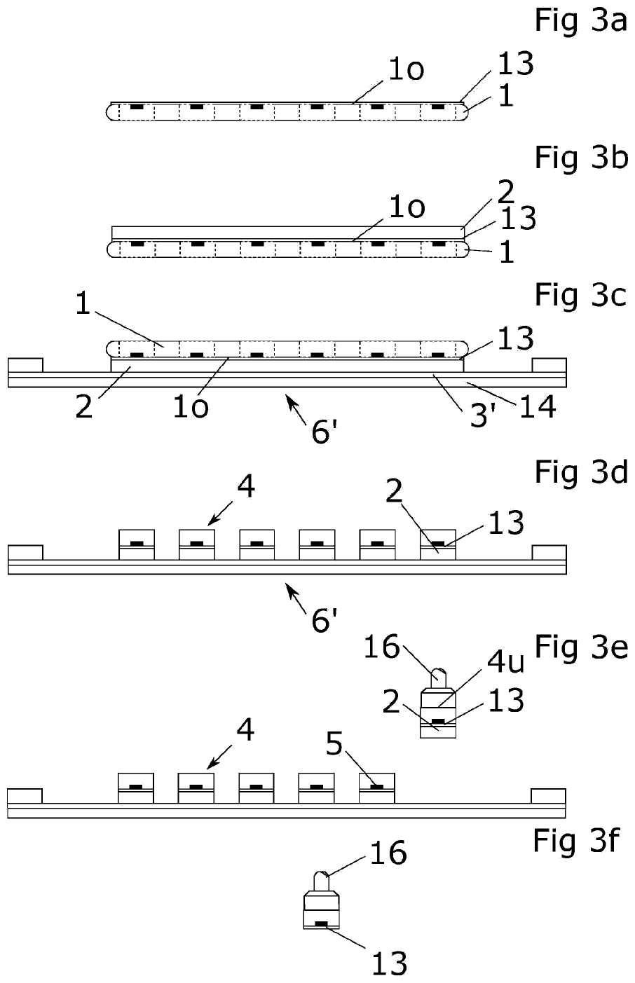

FIG. 3a shows a first process step of a third exemplary method. First substrate 1 is provided at its first substrate surface 1o with a surface treatment 13.

FIG. 3b shows a second process step of a third exemplary method, in which protective layer 2 is deposited directly onto surface treatment 13 of a first substrate surface 1o of a first substrate 1, before first substrate 1 is fixed to second substrate 6′.

FIG. 3c shows a third process step of a third exemplary method, in which first substrate 1 is fixed on second substrate 6′ with its first substrate surface lo, on which surface treatment 13 and protective layer 2 have been produced. Protective layer 2 contacts adhesive layer 3′ of film 14.

FIG. 3d shows a fourth process step of a third exemplary method, in which a separation of first substrate 1 (see FIG. 3c) into individual components 4 takes place. Surface treatment 13 is protected on the one hand by protective layer 2 and on the other hand by the orientation of first substrate 1. The means for the separation of the substrate into single units preferably work first on substrate surface 1u facing away. The influence of the means for the separation into single units is thus minimised in the region of treated surface 13. The separation into single units preferably takes place outside a module system 9.

FIG. 3e shows fifth process step of a third exemplary method, in which components 4 are removed individually and further processed. The removal of components 4, in particular by contacting of a pick-and-place tool 16 at component surface 4u, is particularly advantageous. On the one hand, no contacting takes place at first component surface 1o. An impairment of the treated surface due to the contacting is thus prevented. Furthermore, the component does not have to be rotated for the bonding of the component surface with the product substrate. After the corresponding component has been taken over at the easily accessible component surface 1u by pick-and-place tool 16, component 4 advantageously points with the treated surface to be bonded away from the take-over by pick-and-place tool 16. In comparison with the second exemplary method, pick-and-place tool 16 cannot change or destroy surface treatment 13, since component 4 is contacted at its component surface 4u, which lies opposite surface treatment 13.

FIG. 3f shows a sixth process step of a third exemplary method, in which the removal of protective layer 2 takes place, preferably while component 4 is still held by pick-and-place tool 16. Pick-and-place tool 16 can then bond component 4 with its surface treatment 13 on a further component 4 or a third substrate 8 (not represented).

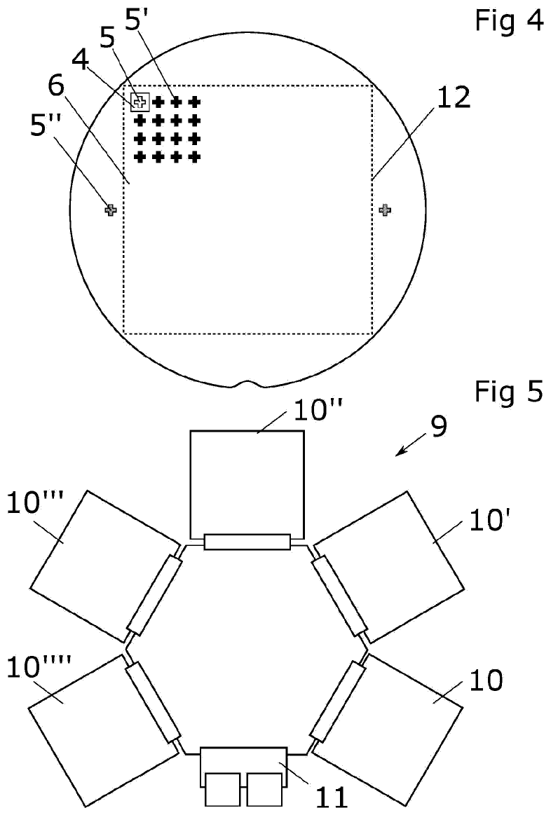

FIG. 4 shows a plan view of a second substrate 6, 6′. A plurality of alignment marks 5′ are distributed over second substrate 6, 6′. By way of example, sixteen alignment marks 5′ are shown. First alignment mark 5′ is concealed by a component 4 with alignment mark 5. A further two alignment marks 5″ are located on second substrate 6, which are used for the alignment of second substrate 6 with product substrate 8 (not shown, see FIG. 1e). Alignment marks 5 (white), 5′ (black) and 5″ (grey) has been coloured differently for a clear view. Components 4 are positioned and bonded exclusively in a component positioning region 12.

FIG. 5 shows a plan view of an exemplary module system 9, comprising a plurality of modules 10, 10′, 10″, 10′″, 10″″. The number of modules is arbitrary. For example, modules 10, 10′, 10″, 10′″, 10″″ are designed as follows. Module 10 represents a coating module, in which bond layer 3 and/or protective layer 2 can be applied (see FIG. 1a). Module 10′ represents a module for separating into single units, in which substrate 1 can be separated into single units (see FIG. 1b). Module 10″ represents an alignment and bonding module, in which individual components 4 can be aligned and positioned on a second substrate 6. Preferably located in this module, therefore, is a type of pick-and-place device. Module 10′″ represents a cleaning module, in which protective layer 2 can be removed. Module 10″″ represents an alignment and bonding module, in which substrates, in particular second substrate 6 equipped with components 4, and a third substrate 8 can be aligned with one another and bonded together.

A task can also be dealt with by a module, if the necessary means are present in the module. It is also conceivable for module system 9 to comprise further modules. In particular, the coating and separation into single units can also take place outside module system 9, so that only already separated components 4 are introduced into module system 9. In this case, the two aforementioned modules 10, 10′ could be left out. Module system 9, in particular the individual modules amongst one another, preferably permits the transfer of components 4 and substrates 6, 8 without the latter being exposed to the atmosphere. Entire module system 9 can thus preferably be evacuated and sealed off with respect to the surrounding atmosphere.

The loading and unloading of all the necessary objects preferably take place via a lock 11, so that the interior of module system 9 can remain evacuated for as long as possible. Module system 9 or individual modules 10, 10′, 10″, 10′″, 10″″ can be evacuated to a pressure less than 1 bar, preferably less than 1 mbar, still more preferably less than 10⁻³ mbar, most preferably less than 10⁻⁹ mbar, with utmost preference up to 10⁻¹² mbar.

### LIST OF REFERENCE NUMBERS

1 First substrate
1o, 1u Substrate surface
2 Protective layer
3, 3′ Bonding layer/adhesive layer
4, 4° Component
4o, 4u Component surface
5, 5′, 5″ Alignment marks
6, 6′ Transfer substrate, second substrate
6o Substrate surface
8 Third substrate/product substrate
9 Module system
10, 10′, 10″, 10′″, 10″″ Module
11 Lock
12 Component positioning region
13 Surface treatment
14 Film
15 Frame
16 Pick-and-place tool

1. A method for the production and preparation of electronic components, comprising:
preparing a first substrate with a first substrate surface and a second substrate surface,
implementing, after the preparing of the first substrate, a surface treatment on the first substrate surface,
applying, after implementing of the surface treatment, a protective layer on the treated first substrate surface, and
separating, after the applying of the protective layer, the substrate into components.

2. The method according to claim 1, wherein the implementing of the surface treatment comprises one or more of cleaning the first substrate surface, a plasma treatment of the first substrate surface, and coating the first substrate surface.

3. The method according to claim 2, wherein the cleaning of the first substrate surface comprises one or more of chemical cleaning and physical cleaning of the first substrate surface.

4. The method according to claim 2, wherein the coating of the first substrate surface takes place with water for hydrophilisation of the first substrate surface.

5. The method according to claim 1, wherein, after the separating of the substrate, each of the components comprises a first component surface and a second component surface, and
wherein the protective layer is applied on the first component surface of each of the components.

6. The method according to claim 5, wherein the components, after the separating of the substrate, are fixed with the second component surface on a carrier substrate.

7. The method according to claim 1, wherein, before the separating of the substrate, the first substrate is provided with the second substrate surface on a second substrate.

8. The method according to claim 1, wherein, before the separating of the substrate, the first substrate is provided with the first substrate surface with the protective layer on the second substrate.

9. The method according to claim 7, wherein the second substrate is a film.

10. The method according to claim 9, wherein the film has an adhesive layer, and the first substrate is fixed on the adhesive layer.

11. The method according to claim 1, further comprising:
removing, after the separating of the substrate, the protective layer from the first component surface of the components.

12. The method according to claim 11, wherein the removing of the protective layer is carried out under a vacuum.

13. The method according to claim 8, wherein, before the separating of the substrate, the first substrate is provided with the first substrate surface with the protective layer on the second substrate,
wherein, before the removing of the protective layer, the components are taken with the first component surface over by a pick-and-place tool and fixed on the pick-and-place tool.

14. The method according to claim 13, wherein the removing of the protective layer takes place while the components are fixed on the pick-and-place tool.

15. A device for the production and preparation of electronic components, comprising:
surface treatment means for implementation of a surface treatment of a first substrate surface of a first substrate, and
means for application of a protective layer on the treated first substrate substrate after the implementation of the surface treatment by the surface treatment means.

16. The device according to claim 15, further comprising:
separation means for the separation of the first substrate into components.

17. The method according to claim 2, wherein the cleaning of the first substrated surface is performed by sputtering.

18. The method according to claim 8, wherein the second substrate is a film.

19. The method according to claim 18, wherein the film has an adhesive layer, and the first substrate is fixed on the adhesive layer.
